(19) United States
(12) Patent Application Publication
(10) Pub. No.: US 2007/0205519 A1
(43) Pub. Date: Sep. 6, 2007

(54) Stacked semiconductor device and device stacking method

(76) Inventor: Yoshikazu Kobayashi, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/713,688

(22) Filed: Mar. 5, 2007

(30) Foreign Application Priority Data
Mar. 6, 2006 (JP) 2006-059367

(51) Int. Cl. H01L 23/52

(52) U.S. Cl. 257/777

(57) ABSTRACT

To prevent wires from contacting an upper device when that upper device is stacked on a device that is bonded to electrodes of a board by wire bonding, a stacked semiconductor device includes a first device bonded to a package board, wires connecting electrodes of the first device to electrodes of the package board, and a second device stacked on the first device through an adhesive member. The adhesive member has a double-layered structure composed of a first die attach film and a second die attach film softer than the first die attach film. The first die attach film prevents the wires from penetrating.

### BACKGROUND OF THE INVENTION

1. Field of the Invention

The present invention relates to a stacked semiconductor device composed of a plurality of stacked devices and to a device stacking method used in the manufacture of such stacked semiconductor device.

2. Related Art

Recently, in an effort to accommodate demands for greater compactness, capacity and performance in electronic devices of all types, multiple devices such as IC, LSI and the like have come to be stacked on a single semiconductor device and packaged. For example, in BGA (Ball Grid Array) and CSP (Chip Size Package) and other such semiconductor devices, a plurality of chip-like devices is stacked one atop the other and sealed in resin. In a stacked semiconductor device of this type, the devices are stacked onto a package board mounted on a printed circuit board, and the electrodes formed in the package board and the electrodes formed in the device are connected to each other, with wire bonding of the electrodes to each other being one type of such connection.

When stacking a plurality of devices atop one other, an adhesive layer is inserted between the upper device and the lower device in order to bond the upper device and the lower device to each other (see, for example, JP-A-2006-54298). Although it is possible to use a paste-like adhesive agent as the attachment layer, ordinarily, a film-like adhesive agent called a die attach film is used.

As shown in FIG. 5, where electrodes 10 formed in a package board 1 and electrodes 20 formed in a first device 2 are connected by wires W, the tops of the wires W, because they are bent in loops, protrude above the level of a top surface 2a of the first device 2. Consequently, when stacking a second device 4 on top of the first device 2, it is necessary to soften the die attach film 9 and bury the wires W inside the die attach film 9.

However, when softening the die attach film 9 and embedding the wires W therein, it sometimes happens that the tops of the wires W push through the die attach film 9 and contact the upper second device 4. When that happens, the wires might break or the second device 4 and the first device 2 might be short-circuited.

### SUMMARY OF THE INVENTION

Accordingly, it is an object of the present invention to solve to prevent the wires from contacting an upper device when that upper device is stacked on top of a device that is bonded to the electrodes of a package board by wire bonding.

According to a first aspect, the present invention relates to a stacked semiconductor device comprises a package board, a first device bonded to a top surface of the package board, a wire connecting an electrode of the package board and an electrode of the first device to each other, a second device stacked on top of the first device, and an adhesive member attaching the first device and the second device to each other. The adhesive member comprises a first die attach film affixed to a bottom surface of the second device and preventing embedding of the wire and a second die attach film affixed to a top surface of the first device and permitting embedding of the wire.

According to a second aspect, the present invention relates to device stacking method suitable for the manufacture of the stacked semiconductor device described above, the device stacking method comprising bonding a first device to a package board, connecting electrodes of the first device and electrodes of the package board to each other by wire bonding, and stacking a second device on top of the first device. A first die attach film affixed to a bottom surface of the second device and preventing embedding of a wire and a second die attach film affixed to a top surface of the first device and permitting embedding of the wire are inserted between the first device and the second device, and the second device is stacked on top of the first device through the first die attach film and the second die attach film.

In such a device stacking method, before the first die attach film is affixed to the bottom surface of the second device, the first die attach film and the second die attach film may be affixed and stacked.

Moreover, in the device stacking method described above, after the first die attach film is affixed to the bottom surface of the second device and the first die attach film is heated and hardened and penetration of the wire prevented, the second die attach film may be affixed to the first die attach film. In this case, the first die attach film and the second die attach film may be formed by the same member.

In the present invention, because the adhesive member inserted between the lower first device and the upper second device is comprised of a double-layer construction consisting of the first die attach film, which is affixed to the bottom of the second device and prevents embedding of the wire, and the second die attach film, which is affixed to the top of the first device and permits embedding of the wire, the wire embedded in the second die attach film does not penetrate the first die attach film. Therefore, the wire can be prevented from contacting the upper second device, and thus the wire does not break, there is no short-circuiting, and so forth. The present invention is such that the stacked semiconductor device remains unaffected even where there are slight difference between the heights of individual wires, thus enabling contact between wire and second device to be prevented and allowing the attachment portion to be made even thinner.

Other features and advantages of the present invention will be apparent from the following description when taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a front view showing an example of a package board;

FIG. 2 is a schematic sectional view showing a state in which a first device is bonded to a package board;

FIG. 3 is a schematic sectional view showing a state in which the electrodes of a first device are bonded to the electrodes of the package board;

FIG. 4 is a schematic sectional view showing a stacked semiconductor device of the present invention; and

FIG. 5 is a schematic sectional view showing a conventional stacked semiconductor device.

### DETAILED DESCRIPTION OF THE PREFERRED EMBODIMENTS

A detailed description will now be given of a preferred embodiment of the present invention, with reference to the accompanying drawings.

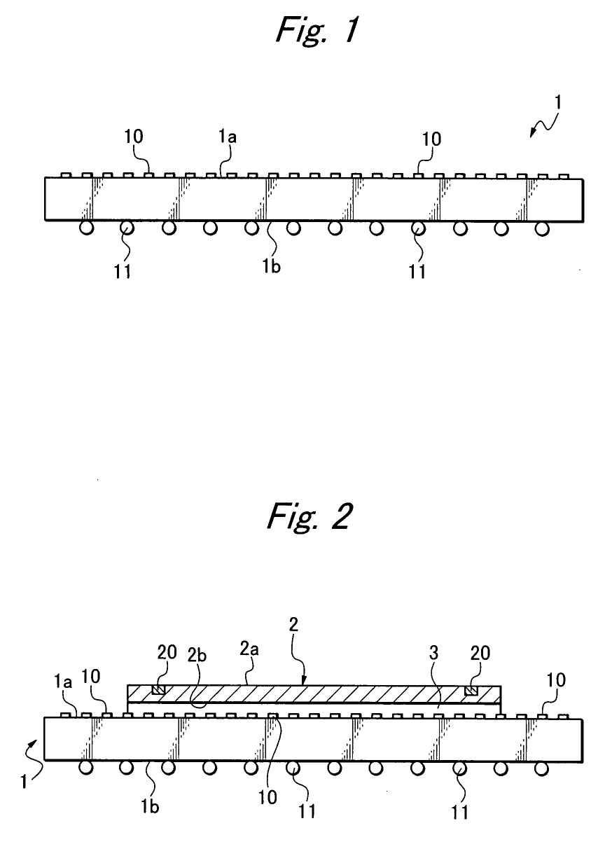

A description is given of stacking two chip-like devices on a top surface 1a side of a package board 1 shown in FIG. 1.

The package board 1 is a board that becomes the base of a package-type semiconductor (BGA, CSP, etc.) mounted on a printed circuit board. A plurality of electrodes 10 that connect to a plurality of electrodes of a device stacked atop the package board 1 are provided on the top surface 1a of the package board 1. By contrast, bumps 11 that connect to terminals of the printed circuit board are formed in a bottom surface 1b of the package board 1.

As shown in FIG. 2, a first device 2 is bonded to the top surface 1a of the package board 1. Such bonding is performed by preliminarily affixing an adhesive agent such as a die attach film 3 that is a film-like adhesive material to a bottom surface 2b of the first device 2, and then affixing the die attach film 3 to a mounting area on the top surface 1a of the package board 1.

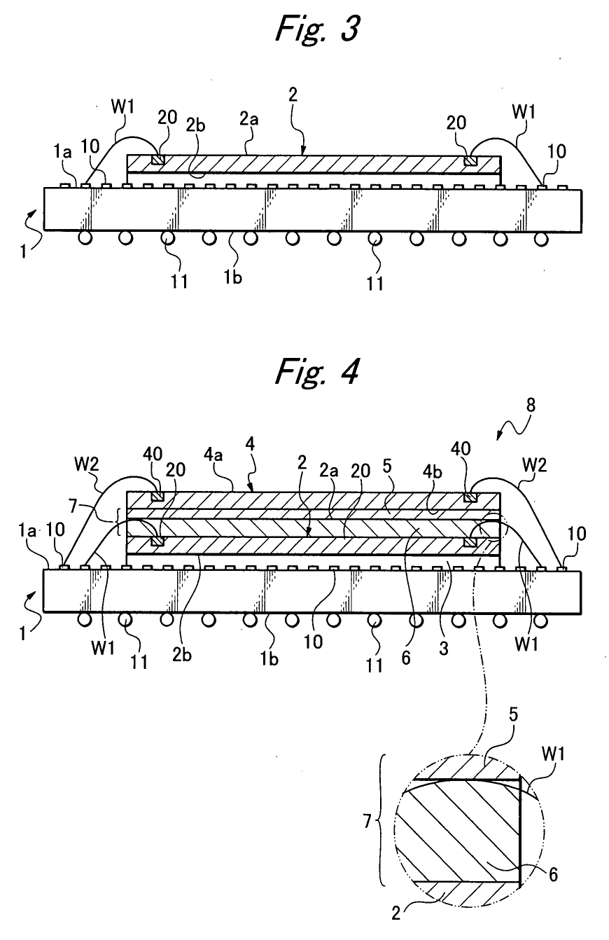

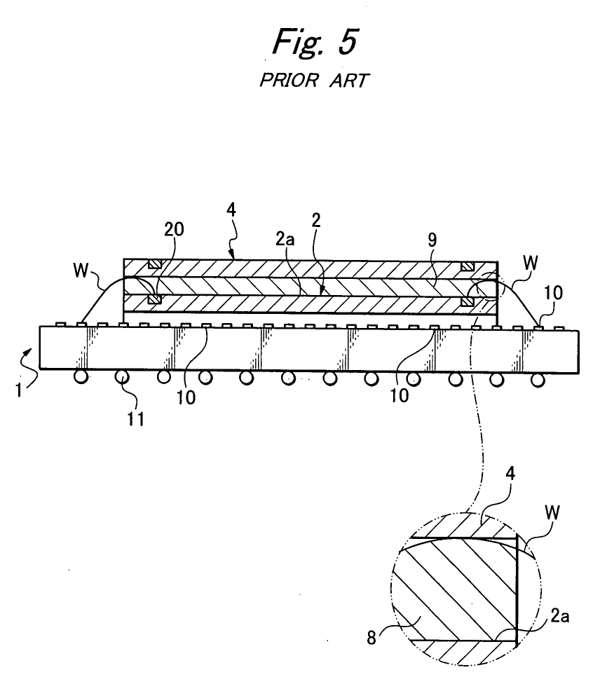

Electrodes 20 are formed in a top surface 2a of the first device 2, as shown in FIG. 2. These electrodes 20 are bridged and connected by wire bonding to electrodes 10 formed in the top surface 1a of the package board 1 by wires W1, as shown in FIG. 3. At this time, the wires W1 are bent in loops, the tops of which are several tens of μm above the top surface 2a of the first device.

Next, as shown in FIG. 4, a second device 4 is stacked on the top surface 2a of the first device 2. A first die attach film 5 is affixed to a bottom surface 4b of the second device 4, and further, a second die attach film 6 is affixed to the first die attach film 5. The second die attach film 6 is made of softer material than the first die attach film 5. Together, the first die attach film 5 and the second die attach film 6 form a double-layered adhesive member 7.

As shown in FIG. 4, the tops of the wires W1 are higher than the top surface 2a of the first device 2. Therefore, when stacking the second device 4 on the first device 2 through the double-layered adhesive member 7, the sides of the wires W1 connected to electrodes 20 of the first device 2 are embedded in the second die attach film 6 of the adhesive member 7. However, since the first die attach film 5 is harder than the second die attach film 6, as shown in the enlargement in FIG. 4 the first die attach film 5 prevents penetration by the wires W1. Therefore, the wires W1 do not contact the first device 2, and there is no break in the wires W1 or short circuit caused by the wires W1.

Next, as shown in FIG. 4, electrodes 40 formed in the second device 4 and the electrodes 10 formed in the package board 1 are connected by wire bonding by wires W2. Thus, as described above, the electrodes 20 formed in the first device 2 and the electrodes 40 formed in the second device 4 are connected to the electrodes 10 of the package board 1, after which the whole is packaged by resin sealing or the like to form a single stacked semiconductor device 8.

It is possible to stack three or more layers of devices on top of the package board 1. For example, in the case of stacking three layers, as with the second-layer device (the second device 4 described above), a double-layered die attach film may be affixed to the bottom surface of the third device, provided that the bottom layer of the die attach film is softer than the top layer of the die attach film.

It should be noted that, since the first device 2 and the second device 4 are formed by dicing a wafer, it is preferable that the first die attach film 5 and the second die attach film 6 be affixed prior to dicing, with the first die attach film 5 and the second die attach film 6 already affixed to the bottom surface of the second device 4 when the chip-like second device 4 is formed by dicing the wafer into individual devices.

In addition, the wires W1 may be made so hard not to allow penetrating the first die attach film 5 during the manufacturing process. In such case, the first die attach film 5 and the second die attach film 6 may be formed by the same member.

The following is a description of several examples of device stacking methods that can be adapted to manufacture of the stacked semiconductor device 8 shown in FIG. 4.

### First Embodiment

Hitachi Chemical Co., Ltd.'s die bonding film DF-402 (thickness 15 μm) is used as the first die attach film 5, and Nippon Steel Chemical Co., Ltd.'s high-performance film adhesive material NEX-130 (thickness 60 μm), which is softer than DF-402 (thickness 15 μm), is used as the second die attach film 6 that together form the double-layered adhesive member 7 shown in FIG. 4.

First, the first die attach film 5 made of the DF-402 (thickness 15 μm) described above and the second die attach film 6 made of the NEX-130 (thickness 60 μm) described above are stacked and heated for 30 seconds at 80 degrees Centigrade to produce the double-layered adhesive member 7. In other words, the double-layered adhesive member 7 is formed before the first die attach film 5 is affixed to the bottom surface 4b of the second device 4.

Then, the first die attach film 5 that forms a part of the adhesive member 7 is affixed to the bottom surface 4b of the second device 4 shown in FIG. 4 and heated for 30 seconds at 80 degrees Centigrade to harden the first die attach film 5 and integrate the second device 4 and the adhesive member 7 into a single unit. It should be noted that the process steps up to this point can also be carried out at the stage of the wafer prior to dicing into the second device 4, in which case the adhesive member 7 is diced together with the wafer.

Next, the second die attach film 6 is heated for 30 seconds at 150 degrees Centigrade to soften it and the second die attach film 6 is compressed to bond onto the top surface 2a of the first device 2 to which the wires W1 shown in FIG. 4 are bonded. As the result, the wires W1 are embedded in the second die attach film 6. However, because the first die attach film 5 is hardened, the wires W1 do not penetrate the first die attach film 5.

Finally, the second die attach film 6 is heated for 60 seconds at 180 degrees Centigrade and hardened, which affixes the second die attach film 6 to the top surface 2a of the first device 2, fixing the second device 4 in place on the first device 2 through the adhesive member 7.

### Second Embodiment

As with the first embodiment described above, a second embodiment of the present invention also uses Hitachi Chemical Co., Ltd.'s die bonding film DF-402 (thickness 15 μm) as the first die attach film 5, and Nippon Steel Chemical Co., Ltd.'s high-performance film adhesive material NEX-130 (thickness 60 μm), which is softer than DF-402 (thickness 15 μm) as the second die attach film 6 that together form the double-layered adhesive member 7 shown in FIG. 4.

First, the first die attach film 5 made of the DF-402 (thickness 15 μm) described above is heated for 30 seconds at 80 degrees Centigrade, affixed to the bottom surface 4b of the second device and hardened. Then, the second die attach film 6 made of the NEX-130 (thickness 60 μm) described above is heated for 30 seconds at 80 degrees Centigrade, and affixed to the first die attach film 5 that is already affixed to the bottom surface 4b of the second device 4. The process steps up to this point can also be carried out at the stage of the wafer prior to dicing into the second device 4, in which case the adhesive member 7 is diced together with the wafer.

Thereafter, the second die attach film 6 is heated for 30 seconds at 150 degrees Centigrade to soften it, the second die attach film 6 is compressed to bond onto the top surface 2a of the first device 2, the wires W1 are embedded in the second die attach film 6, and the second die attach film 6 is further heated for 60 seconds at 180 degrees Centigrade and hardened, stacking the second device 4 on the first device 2 through the double-layered adhesive member 7 composed of the first die attach film 5 and the second die attach film 6.

As with the first embodiment, in the present method as well the first die attach film 5 is already hardened when the wires W1 are embedded in the second die attach film 6, and therefore the wires W1 do not penetrate the first die attach film 5.

### Third Embodiment

A third embodiment of the present invention uses the same member, for example Nippon Steel Chemical Co., Ltd.'s high-performance film adhesive material NEX-130 (thickness 60 μm), for both the first die attach film 5 and the second die attach film 6 that together form the double-layered adhesive member 7 shown in FIG. 4.

First, the first die attach film 5 composed of NEX-130 is affixed to the bottom surface 4a of the second device 4 and heated for 60 seconds at 180 degrees Centigrade to harden it. Then, the second die attach film 6, also composed of NEX-130, is heated to 150 degrees Centigrade and softened, after which it is affixed to the hardened first die attach film 5 as well as compressed to bond onto the top surface 2a of the first device 2. As the result, the wires W1 bonded to the electrodes 20 of the first device 2 are embedded in the softened second die attach film 6. Then the second die attach film 6 is further heated for 60 seconds at 180 degrees Centigrade and hardened, thereby stacking the second device 4 on the first device 2 through the double-layered adhesive member 7 composed of the first die attach film 5 and the second die attach film 6.

With the above-described method, the first die attach film 5 is already hardened when the second die attach film 6 is softened and the wires W1 are embedded therein, and thus the wires W1 do not penetrate the first die attach film 5 even though the same material is used for both the first die attach film 5 and the second die attach film 6.

As many apparently widely different embodiments and variations of the present invention can be made without departing from the spirit and scope thereof, it is to be understood that the present invention is not limited to the specific embodiments thereof described herein but rather only to the extent set forth in the following claims.

What is claimed is:

1. A stacked semiconductor device comprising:
a package board;
a first device bonded to a top surface of said package board;
a wire connecting an electrode of said package board and an electrode of said first device to each other;
a second device stacked on top of said first device; and
an adhesive member attaching said first device and said second device to each other,
wherein said adhesive member comprising:
a first die attach film affixed to a bottom surface of said second device and preventing embedding of said wire; and
a second die attach film affixed to a top surface of said first device and permitting embedding of said wire.

2. A device stacking method comprising the steps of
bonding a first device to a package board;
connecting electrodes of said first device and electrodes of said package board to each other by wire bonding; and then
stacking a second device on top of said first device,
wherein a first die attach film affixed to a bottom surface of said second device preventing embedding of a wire and a second die attach film affixed to a top surface of said first device and permitting embedding of said wire are inserted between said first device and said second device and said second device is stacked on said first device through said first die attach film and said second die attach film.

3. The device stacking method according to claim 2, wherein said first die attach film and said second die attach film are affixed and stacked before said first die attach film is affixed to the bottom surface of said second device.

4. The device stacking method according to claim 2, wherein said first die attach film is affixed to a rear surface of said second device, heated, and hardened to prevent penetration by the wire, after which said second die attach film is affixed to said hardened first die attach film.

5. The device stacking method according to claim 4, wherein said first die attach film and said second die attach film are formed of identical material.
